(19) United States
(12) Patent Application Publication
(10) Pub. No.: US 2009/0066428 A1
(43) Pub. Date: Mar. 12, 2009

(54) DEVICE FOR PROVIDING AN A.C. SIGNAL

(75) Inventor: Franck Badets, Voiron (FR)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics S.A., Montrouge (FR)

(21) Appl. No.: 12/171,159

(22) Filed: Jul. 10, 2008

(30) Foreign Application Priority Data
Jul. 12, 2007 (FR) 07/56440

(51) Int. Cl. H03B 1/00; H03B 28/00

(52) U.S. Cl. 331/49; 977/838

(57) ABSTRACT

A circuit for providing an A.C. signal including a number N of nanomagnetic oscillators, N being an integer greater than or equal to 2, each nanomagnetic oscillator providing a periodic signal; a unit for providing a control signal that can take N values, each periodic signal being associated with one of the values of the control signal; and a multiplexer receiving the N periodic signals and the control signal and providing the A.C. signal equal to one of the periodic signals according to the value of the control signal.

### BACKGROUND OF THE INVENTION

1. Field of the Invention

The present invention relates to a device for providing an A.C. signal.

2. Discussion of the Related Art

Many electronic systems use a device dedicated to the provision of a periodic A.C. signal which forms a time reference. A first example corresponds to a system for providing radio-frequency signals which uses one or several periodic reference signals to provide the radio-frequency signals. A second example corresponds to a digital circuit which is rated by one or several periodic reference signals, generally called clock signals.

A device for providing a periodic A.C. signal used as a reference signal needs to fulfill several constraints. First, the device needs to provide the reference signal with a sufficient frequency accuracy according to the desired application. As an example, for global system for mobile communications or GSM radio-frequency signal transmission systems, the required accuracy is 0.1 ppm. Second, the frequency of the reference signal needs to remain sufficiently stable according to parameters such as temperature, the supply voltage, or the aging of the reference signal supply device. Third, the reference signal noise level needs to be sufficiently low.

In conventional electronic circuits, the device for providing a reference signal generally corresponds to a quartz oscillator providing a periodic signal having a frequency depending on the mechanical properties of quartz. An advantage of a quartz oscillator is that it enables obtaining, after a trimming step, a reference signal with a high frequency accuracy. Another advantage is the high stability of the reference signal frequency with respect to temperature, the oscillator supply voltage, aging, etc.

However, a quartz oscillator has several disadvantages. A first disadvantage is that, when the reference signal is intended for an integrated electronic circuit, the quartz oscillator cannot be formed in integrated fashion with the other electronic circuit components. The quartz oscillator then corresponds to a separate circuit connected to the electronic circuit by wire connections. The assembly formed by the electronic circuit and the quartz oscillator thus exhibits a significant bulk. Further, access pads dedicated to receiving the reference signal need to be provided at the level of the electronic circuit, which causes an increase in the size of said electronic circuit. Second, the quartz oscillator trimming step has a high cost. Third, quartz oscillators available for sale provide signals with frequencies generally smaller than some hundred megahertz. Given that, for many applications, it is necessary to use a reference signal of higher frequency, especially greater than one gigahertz, the electronic circuit, receiving the reference signal provided by the quartz oscillator, needs to comprise means for increasing the reference signal frequency.

The previously-mentioned constraints result in that, conventionally, to limit the cost and the general bulk of an electronic system, all the reference signals necessary to the proper operation of the electronic system are obtained from a single reference signal provided by a single quartz oscillator. The characteristics of this single oscillator need to then be defined according to all the reference signals used by the electronic system. Defining the optimal characteristics of the oscillator may be difficult.

Another example of application of a device for providing an A.C. signal corresponds to the forming of a frequency synthesizer. A conventional frequency synthesizer, for example, comprises a quartz oscillator supplying a phase-locked loop or PLL. The previously-mentioned disadvantages specific to the use of a quartz oscillator then reappear.

### SUMMARY OF THE INVENTION

Thus, an embodiment of the present invention aims at a device for providing an A.C. signal that can be formed at decreased cost and capable of being integrated in an electronic circuit.

An embodiment of the present invention provides a circuit for providing an A.C. signal comprising a number N of nanomagnetic oscillators, N being an integer greater than or equal to 2, each nanomagnetic oscillator providing a periodic signal; a unit for providing a control signal that can take N values, each periodic signal being associated with one of the values of the control signal; and a multiplexer receiving the N periodic signals and the control signal and providing the A.C. signal equal to one of the periodic signals according to the value of the control signal.

According to an embodiment, the circuit further comprises an amplifier receiving the A.C. signal and providing an amplified signal.

According to an embodiment, the circuit further comprises a divider receiving the amplified signal and providing an output signal, the frequency of the output signal being smaller than the frequency of the amplified signal.

According to an embodiment, the N nanomagnetic oscillators are capable of providing the periodic signals at a same frequency plus or minus the frequency dispersions of the nanomagnetic oscillators.

According to an embodiment, the circuit further comprises a frequency divider receiving said A.C. signal and providing an additional A.C. signal, where the divider can apply to the A.C. signal a division coefficient from among M division coefficients, M being an integer at least equal to 2; and a delta-sigma converter receiving a set point indicating a desired frequency value and providing an additional control signal that can take M values, the value of the additional control signal being capable of changing on each rising or falling edge of the additional A.C. signal, each division coefficient being associated with one of the M values of the additional control signal, the successive durations of the halfwaves of the additional A.C. signal corresponding to the successive values of the control signal, the A.C. signal exhibiting a frequency equal, on average, to the desired frequency.

According to an embodiment, the unit is a delta-sigma converter receiving a set point indicating a desired frequency value, the value of the control signal being capable of changing on each rising or falling edge of the A.C. signal, and the frequency of each periodic signal is equal to one of N predefined frequency values, the successive durations of the halfwaves of the A.C. signal corresponding to the successive values of the control signal, the A.C. signal exhibiting a frequency on average equal to the desired frequency.

According to an embodiment, the circuit further comprises an injection locked oscillator receiving said A.C. signal or the additional A.C. signal and providing an output signal.

According to an embodiment, the locking frequency range of the oscillator comprises a frequency equal to an integral multiple of said desired frequency.

According to an embodiment, at least one nanomagnetic oscillator comprises a first portion of a magnetic material in which the orientations of the spins of the particles of the first portion are set, a second portion of a magnetic material in which the orientations of the spins of the particles of the second portion are capable of varying, and a third portion of an at least partially conductive material interposed between the first and second portions; a current source comprising a first terminal connected to the first portion and a second terminal connected to the second portion; and a source capable of applying a magnetic field on the first and second portions.

The foregoing objects, features, and advantages of the present invention will be discussed in detail in the following non-limiting description of specific embodiments in connection with the accompanying drawings.

### BRIEF DESCRIPTION OF THE DRAWINGS

FIG. 1 schematically shows an embodiment of a nanomagnetic oscillator;

FIG. 2 shows an embodiment of a device for providing a reference signal;

FIG. 3 shows another embodiment of a device for providing a reference signal;

FIGS. 4A to 4C illustrate the operation of the device of FIG. 3;

FIG. 5 shows an embodiment of a frequency synthesizer;

FIG. 6 shows an example of a timing diagram illustrating the operation of the synthesizer of FIG. 5; and

FIG. 7 shows another embodiment of a frequency synthesizer.

### DETAILED DESCRIPTION

For clarity, the same elements have been designated with the same reference numerals in the different drawings.

Generally, an embodiment of the present invention provides a device for providing an A.C. signal using several nanomagnetic oscillators. Examples of nanomagnetic oscillators are described in the publication “Theory of Magnetodynamics Induced by Spin Torque in Perpendicularly Magnetized Thin Films” of M. A. Hoefer, M. J. Ablowitz, B. Ilan, M. R. Pufall, and T. J. Silva published in The American Physical Society, Physical Review Letters 95, 267206 (2005) and publication “Frequency modulation of spin-transfer oscillators” of M. R. Pufall, W. H. Rippard, S. Kaka, T. J. Silva, S. E. Russek, published in American Institute of Physics, Applied Physics Letters 86, 082506 (2005).

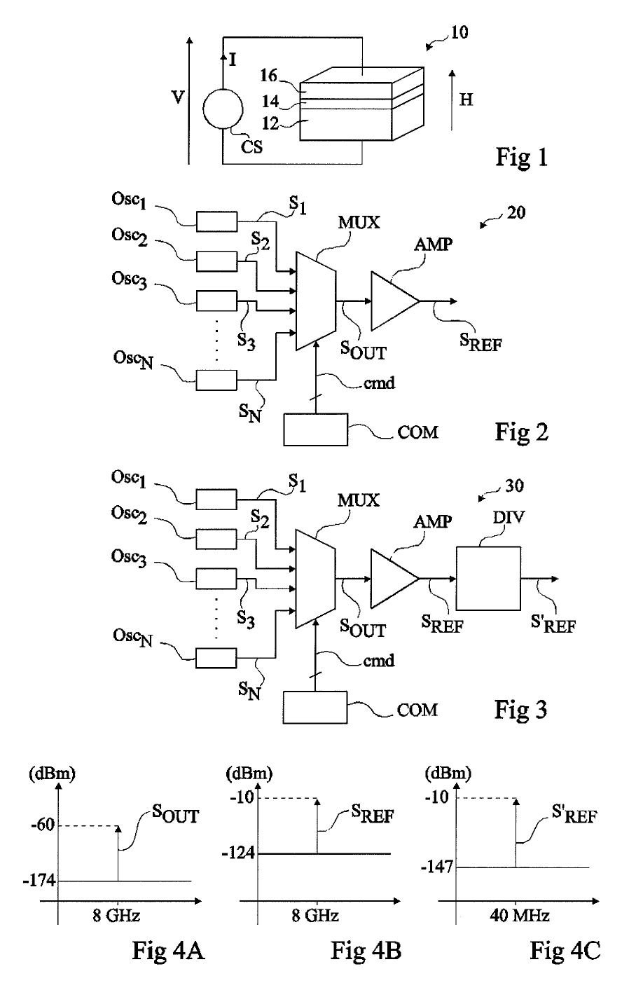

FIG. 1 schematically shows an embodiment of a nanomagnetic oscillator 10. Oscillator 10 is formed of the stack of three layer portions 12, 14, 16 each having, for example, a base surface area corresponding to a square with a 150-nanometer side and having a thickness on the order of some ten nanometers. Portion 12 corresponds to a magnetic material, for example, an iron and cobalt alloy, for which the orientation of the spins of the particles of portion 12 is set. Portion 12 is generally called a fixed layer. Portion 14 corresponds to a separation layer and may be made of copper or of magnesium oxide. Portion 16 corresponds to a magnetic material, for example, a nickel and iron alloy. The orientations of the spins of the particles of portion 16 are likely to be modified. Portion 16 is generally called a free layer. A current source CS is connected to oscillator 10 and is capable of running a constant current I through the stacking of layer portions 12, 14, 16. Oscillator 10 is placed in a magnetic field H, possibly inclined with respect to the stack direction of layer portions 12, 14, 16. Call V the voltage across oscillator 10.

Under certain conditions, especially for specific dimensions of layer portions 12, 14, 16, and/or contact areas between current source CS and oscillator 10, a sustained precession motion of the spins of free area 16, which translates as sustained oscillations of voltage V, can be observed. The oscillation frequency of voltage V especially depends on the amplitude and on the orientation of magnetic field H and on the intensity of current I. Typically, the obtained oscillation frequencies vary from 1 to 20 gigahertz. The power of the periodic signal provided by oscillator 10 is generally low, for example, lower than −60 dBm.

An advantage of oscillator 10 is that it can be made to be integrated to a semiconductor-based circuit. A disadvantage of oscillator 10 is that the accuracy of the frequency of the periodic signal is generally low. Further, the stability of the frequency of the periodic signal regarding parameters such as temperature, aging, etc. may also be low. Nanomagnetic oscillator 10 is thus not capable of being directly used to form a device for providing an A.C. signal for conventional electronic applications, especially to form a device for providing a periodic reference signal or a frequency synthesizer.

A circuit for providing an A.C. signal will now be described for the provision of a periodic reference signal.

FIG. 2 shows an embodiment of a device 20 for providing a reference signal S_{REF}. Device 20 comprises a number N of nanomagnetic oscillators Oscᵢ, with i being an integer varying between 1 and N, N being an integer at least equal to 2. Each nanomagnetic oscillator Oscᵢ may have the structure of oscillator 10 shown in FIG. 1. The control circuits (current source, magnetic field source) of each oscillator Oscᵢ are not shown. In particular, all oscillators Oscᵢ, or at least part of them, may be connected to a same current source. Each oscillator Oscᵢ provides a periodic signal Sᵢ to an input of a multiplexer MUX. Multiplexer MUX is controlled by a control signal cmd provided by a control unit COM. Control signal cmd may take several values, one of periodic signals Sᵢ being associated with each value. Multiplexer MUX provides a signal S_{OUT} which is equal to one of periodic signals Sᵢ according to the value of control signal cmd. As an example, control signal cmd is a binary signal that can take at least N values, the provision by multiplexer MUX of one of signals Sᵢ corresponding to each value of control signal cmd. Signal S_{OUT} drives the input of an amplifier AMP which amplifies signal S_{OUT} and provides reference signal S_{REF}.

The desired frequency of signal S_{REF} may be known in advance. In this case, oscillators Oscᵢ are defined to provide the periodic signals Sᵢ corresponding to the desired frequency plus or minus the frequency dispersion. The present embodiment of device 20 enables overcoming the low accuracy of the frequency of the periodic signals provided by nanomagnetic oscillators Oscᵢ. Indeed, by taking into account the frequency dispersion of nanomagnetic oscillators Oscᵢ, number N of oscillators is selected to be large enough to ensure for at least one of oscillators Oscᵢ, with i ranging from 1 to N, to provide a periodic signal Sᵢ having a frequency sufficiently close to the desired frequency, even if, on manufacturing of device 20, that of oscillator Oscᵢ which provides periodic signal Sᵢ at the right frequency is not known in advance. The frequency of signal S_{REF} which is desired to be obtained cannot be known in advance while belonging to a given frequency range. In this case, the number of oscillators Oscᵢ and the properties of each of them are determined by taking into account the dispersions of the oscillators, to ensure that at least one of oscillators Oscᵢ, with i varying from 1 to N, provides a periodic signal Sᵢ having a frequency sufficiently close to the desired frequency in the frequency range.

According to a first example of use of device 20, a previous step of setting of device 20 may be provided, in which control unit COM provides control signal cmd at different successive values so that signal S_{OUT} is successively equal to each of periodic signals S₁ to S_{N}. The frequency of the obtained reference signal S_{REF} is then compared with the desired frequency and the value for which the frequency of signal S_{REF} is closest to the desired frequency is kept as the value of control signal cmd.

According to an example of use of device 20, for a specific application according to which the electronic system, comprising device 20, is used for the provision of radio-frequency signals, the electronic system may receive a radio-frequency calibration signal, regularly transmitted by a base station, which is representative of the frequency of the reference signal to be used by the electronic system. In this case, the selection of oscillator Oscᵢ, with i varying from 1 to N, adapted to the provision of signal S_{REF} at the right frequency, is performed each time a new value of the calibration signal is received by the electronic system.

Device 20 for providing a reference signal may be made in integrated form in several forms on the same electronic circuit to provide the different reference signals used by the electronic circuit. The low bulk of each nanomagnetic oscillator Oscᵢ enables, even if a high number N of oscillators Oscᵢ is provided for each device 20, for the general bulk of the assembly of devices 20 to remain much lower than that which would be obtained by using a quartz oscillator.

As an example, considering that the frequency accuracy of an oscillator Oscᵢ is 20%, for the accuracy of device 20 for providing a reference signal to be of 20 ppm, it is necessary to provide 10⁴ oscillators. The surface area taken up by an oscillator Oscᵢ being on the order of some nm², the total surface area taken up by the oscillators is on the order of a few μm².

FIG. 3 shows another embodiment of a device 30 for providing a reference signal adapted to the case where the noise floor of periodic signal Sᵢ provided by each oscillator Oscᵢ is high with respect to the “useful” power of signal Sᵢ. Device 30 uses all the elements of device 20 shown in FIG. 2 and further comprises a divider DIV receiving the periodic reference signal S_{REF} and providing a periodic reference signal S′_{REF} having a frequency corresponding to the frequency of signal S_{REF} divided by a division ratio RD. Divider DIV may have a conventional structure and comprise a counter rated by signal S_{REF}. The counter is a counter modulo Rd. Each time the counter returns to 0, it provides a pulse. A.C. signal S′_{REF} provided by the counter then is a sequence of spaced-apart pulses, each halfwave of the signal being formed of a pulse at level “1” followed by a stage at level “0”.

The use of a divider DIV has the advantage that the amplitude of signal S′_{REF} remains substantially equal to the amplitude of signal S_{REF} while the noise floor of signal S′_{REF} is divided, with respect to the noise floor of signal S_{REF}, by division ratio RD.

FIGS. 4A to 4C illustrate the principle of the decrease of the noise floor of signal S′_{REF} obtained by device 30.

In FIG. 4A, the power spectrum of signal S_{OUT} has been schematically shown. As an example, for a conventional nanomagnetic oscillator, there is a line at 8 GHz corresponding to a −60-dBm “useful” frequency and a noise floor on the order of −174 dBm.

The power spectrum of signal S_{REF} obtained by amplification of signal S_{OUT} has been schematically shown in FIG. 4B. For the “useful” power of signal S_{OUT} to be sufficient for conventional electronics applications, the amplification ratio of amplifier AMP is selected for the 8-GHz line of signal S_{REF} to be at least at −10 dBm. The noise floor of signal S_{REF} then is at −124 dBm. The noise floor of amplifier AMP being, for example, on the order of −150 dBm, the noise floor of signal S_{REF} is due to the amplification of the noise floor of signal S_{OUT}.

The power spectrum of signal S′_{REF}, with division ratio RD being equal to 200, has been schematically shown in FIG. 4C. A 40-MHz line for which the power always is −10 dBm can then be observed. However, the noise floor has decreased by −46 dB.

The A.C. signal provision device shown in FIG. 2 or 3 may be modified to form a voltage-controlled oscillator. Indeed, for each oscillator Oscᵢ, the oscillation frequency of signal Sᵢ provided by oscillator Oscᵢ depends on the amplitude of the current flowing through oscillator Oscᵢ. Thereby, by supplying each oscillator Oscᵢ with a variable current source controlled by a current set point, the frequency of signal S_{REF} may be modified by varying the current set point. Such a current-controlled oscillator may be used in a phase-locked loop or PLL.

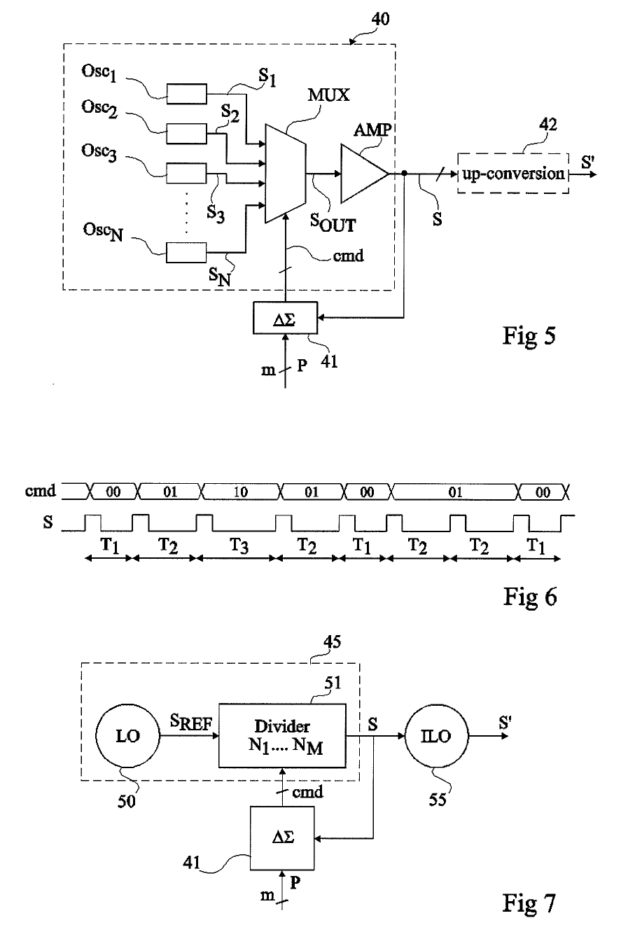

FIG. 5 shows an embodiment of a frequency synthesizer according to the present invention based on the operating principle described in French patent FR 06/52964 filed by the applicant, which is incorporated herein by reference.

In the following description, it is considered that an A.C. signal is formed of several halfwaves. On each halfwave, the signal varies between values qualified as “high” and values qualified as “low”. An example of an A.C. signal is a sequence of pulses or, in other words, a sequence of rectangular pulses between a high level and a low level, for example, “1” and “0”, each halfwave of the signal then being formed of a phase at 1 and of a phase at 0. Other examples of A.C. signals are a sawtooth signal and a sinusoidal signal. On each halfwave of an A.C. signal, a rising edge may be defined when the signal value increases and a falling edge may be defined when the signal value decreases. For a given A.C. signal type, each halfwave starts with the same value and ends on the same value. Further, each of the signal halfwaves has a substantially identical shape, that is, a substantially identical variation direction of the signal values during the halfwave. However, the halfwave durations may be different.

As shown in FIG. 5, the synthesizer comprises a coherent multiple-frequency generation device 40 controlled by a delta-sigma converter 41. Delta-sigma converter 41 receives a frequency set point P, corresponding to a digital signal coded over m bits, and provides control signal cmd to the coherent multiple-frequency generation device 40. Device 40 provides an A.C. signal S having its frequency depending on control signal cmd. The operations of delta-sigma converter 41 are rated by signal S.

Device 40 comprises the elements of device 20 shown in FIG. 2, with delta-sigma converter 41 replacing control unit COM and multiplexer MUX being controlled by control signal cmd provided by delta-sigma converter 41. Device 40 may also have the structure of device 30 shown in FIG. 3. However, oscillators Oscᵢ are defined from the start to provide periodic signals at clearly distinct frequencies. Call frequencies f₁ to f_{N} the frequencies of periodic signals S₁ to S_{N} provided by oscillators Osc₁ to Osc_{N}. Control signal cmd may take N values. The value of control signal cmd is capable of changing on each rising edge or on each falling edge of A.C. signal S.

A.C. signal S is a series of halfwaves having their durations defined according to control signal cmd. More specifically, the duration of each halfwave is equal to one of N predefined period values T₁ to T_{N}. Each period T₁ to T_{N} corresponds to a frequency f₁ to f_{N}, with f₁=1/T₁ and so on. Frequencies f₁ to f_{N} are of increasing values, that is, f₁ is the lowest frequency and f_{N} is the highest frequency. Each period T₁ to T_{N} is associated with one of the N possible values of control signal cmd. The successive durations of the halfwaves of signal S are thus defined according to the successive values of control signal cmd.

The frequency synthesizer may play the role of a transmitter which transposes a low-frequency modulation (modulation of signal P) containing useful data to higher frequencies (signal S) to enable propagation of the signal. The spectrum of the transmitted signal is formed of a so-called carrier signal with a frequency depending on the average of signal P and of adjacent lobes which contain the useful data.

Control signal cmd generated by delta-sigma converter 41 is such that A.C. signal S provided by device 40 exhibits in average a frequency equal to frequency set point P.

FIG. 6 is a timing diagram illustrating an example of an A.C. signal S and of an associated control signal cmd. A.C. signal S is a series of rectangular pulses between two binary values 0 and 1. Each halfwave of signal S comprises a first phase at 1 and a second phase at 0 and starts with a rising edge from 0 to 1. Eight halfwaves of signal S are shown. The value of signal cmd changes after each rising edge of the shown halfwaves, except after the seventh halfwave. In this example, control signal cmd may take 3 binary values “00”, “01”, and “10”. The values taken by signal cmd successively are 00, 01, 10, 01, 00, 01, and 00. Values “00”, “01”, and “10” of signal cmd respectively correspond to three period values T₁, T₂, and T₃ (T₁<T₂<T₃) of A.C. signal S.

In this example, the duration of a halfwave is a function of the value taken by signal cmd during this halfwave or more specifically little after the initial rising edge of this halfwave. The time required for the possible switching of control signal cmd at the beginning of each halfwave of signal S corresponds to the “response” time of the delta-sigma converter after the reception of a rising edge of signal S. The duration of the first halfwave is T₁ since signal cmd is set to 00 during this first halfwave, the duration of the second halfwave is T₂ since signal cmd is set to 01 during this second halfwave, and so on.

According to an alternative operation of the synthesizer shown in FIG. 5, the duration of a halfwave is determined by the value of signal cmd at the very time of the initial rising edge of this halfwave. In other words, the duration of a halfwave is a function of the value taken by signal cmd at the end of the previous halfwave.

Frequency set point P applied to the delta-sigma converter may be fixed or variable along time. In the case where set point P is variable, its variation frequency need to be lower than frequency f₁ of device 40 to ensure a proper operation of the circuit.

The frequency spectrum of A.C. signal S comprises, when set point P is constant, a central line at a frequency which depends on the value of set point P and on the quantization noise rises introduced by delta-sigma converter 41 around this central line. When a low-frequency modulation is applied to set point P, the spectrum of signal S further comprises one or several lobes at the level of the central line.

Delta-sigma converter 41 may be formed in various known manners. A delta-sigma converter will preferably be selected, which introduces into A.C. signal S a mainly high-frequency noise as compared with the desired frequencies of signal S which form the “useful” portion of signal S. Such a high-frequency noise avoids disturbing the useful portion of signal S and can easily be filtered if necessary.

It should further be noted that for a given frequency set-point value P, frequency f of A.C. signal S belongs to frequency range [f₁; f_{N}]. The resolution of frequency f of A.C. signal S is a function of the accuracy with which frequency set point P may be set. The number of possible frequencies f is 2ⁱ, i being the number of bits of set point P. The interval between two possible values of frequency f is equal to (f_{N}-f₁)/2ⁱ. As an example, frequency set point P corresponds to an integral value coded over 16 bits and frequency range [f₁; f_{N}] is equal to [340 MHz; 370 MHz]. The number of possible frequencies f then is 2¹⁶ and the interval between two possible values of frequency f is equal to 30 MHz divided by 2¹⁶, that is, approximately 458 Hz.

In the case where an A.C. signal S of frequency f greater than the maximum operating frequency of the delta-sigma converter or of coherent multiple-frequency generation device 40 is desired to be generated, it is possible to add an “up-conversion” frequency converter 42 to the synthesizer shown in FIG. 5. Converter 42 then transforms A.C. signal S of frequency f into an A.C. signal S′ of frequency f′ greater than f.

According to a variation of the frequency synthesizer shown in FIG. 5, instead of each oscillator Oscᵢ, or at least of some of them, a device 20 for providing a periodic signal such as shown in FIG. 2 may be provided.

FIG. 7 is another embodiment of a frequency synthesizer in which the coherent multiple-frequency generation device 45 is formed of a local oscillator 50 (LO) providing a signal S_{REF} of fixed frequency f_{ref} to a frequency divider 51. Local oscillator has the structure of the reference signal provision device shown in FIG. 2. Divider 51 provides A.C. signal S of frequency f, f being smaller than f_{ref}. More specifically, frequency f is an integral sub-multiple of frequency f_{ref}, ratio f_{ref}/f being equal to one of M integers N₁ to N_{M}, M being an integer at least equal to 2. The ratio applied by the divider is equal to N₁ if a halfwave of signal S of duration T₁ is desired to be obtained, equal to N₂ if a halfwave of duration T₂ is desired to be obtained, and so on. The division ratio applied by divider 51 is a function of control signal cmd provided by delta-sigma converter 41. In the present embodiment, control signal cmd can take M values. Division ratios N₁ to N_{M} are associated with the M possible values of control signal cmd.

Divider 51 is for example formed of a counter rated by signal S_{REF}. The counter is a counter modulo Nᵢ, where Nᵢ is the value of the division ratio selected by signal cmd, with i ranging between 1 and M. Each time the counter returns to 0, it provides a pulse. A.C. signal S provided by the counter then is a series of spaced-apart pulses, each halfwave of the signal being formed of a pulse at level “1” followed by a stage at level “0”.

In the synthesizer example shown in FIG. 7, converter 42 which performs a frequency transposition is an injection locked oscillator 55 (ILO).

A locked oscillator may be formed of a resonant circuit corresponding to a capacitor and a coil in parallel. The oscillator may also be of relaxation or ring type. The oscillator is provided to “naturally” oscillate at a frequency fₙₐₜ. When the natural flow of the charges through the capacitor and the coil is modified, for example by means of current generators controlled by an A.C. current, it is possible to modify the frequency of the oscillations of the oscillator. More specifically, the oscillation frequency becomes equal to frequency f_{INJ} of the “injected” A.C. signal when f_{INJ} is sufficiently close to natural frequency fₙₐₜ, or in other words when frequency f_{INJ} belongs to a lock frequency range [fᵥ₁; fᵥ₂] centered on frequency fₙₐₜ.

For injection locked oscillator 55 to operate as a frequency converter to transform a “low” frequency A.C. signal S into a “high”-frequency A.C. signal S′, oscillator 55 is provided to lock on a harmonic of frequency f of A.C. signal S delivered by divider 51. More specifically, the spectrum of A.C. signal S comprises main lines corresponding to the desired frequencies belonging to frequency range [f₁; f_{M}] and secondary lines, or harmonics, corresponding to integral multiples of the desired frequencies belonging to the secondary frequency ranges [2f₁; 2f_{M}], [3f₁; 3f_{M}], [4f₁; 4f_{M}], [5f₁; 5f_{M}] and so on. Thus, to obtain an A.C. signal S′ of frequency f equal to k times frequency f of A.C. signal S, lock frequency range [fᵥ₁; fᵥ₂] of oscillator 55 needs to comprise secondary frequency range [kf₁; kf₂]. Integer k is called hereafter the conversion ratio of oscillator 55.

It should be noted that injection-locked oscillator 55 filters all or part of the noise introduced into A.C. signal S by the presence of delta-sigma converter 41.

Further, in the case where the frequency of A.C. signal S is not desired to be converted, an injection-locked oscillator may be used as a band-pass filter to obtain an A.C. signal S′ only corresponding to the useful portion of A.C. signal S.

Specific embodiments of the present invention have been described. Various alterations and modifications will occur to those skilled in the art. In particular, those skilled in the art may devise other embodiments of frequency converter 42. Converter 42 may be formed by means of a phase-locked loop.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A circuit for providing an A.C. signal comprising:
a number N of nanomagnetic oscillators, N being an integer greater than or equal to 2, each nanomagnetic oscillator providing a periodic signal, the N nanomagnetic oscillators being adapted to provide the periodic signals at a same frequency plus or minus the frequency dispersions of the nanomagnetic oscillators;
a unit for providing a control signal that can take N values, each periodic signal being associated with one of the values of the control signal; and
a multiplexer receiving the N periodic signals and the control signal and providing the A.C. signal equal to one of the periodic signals according to the value of the control signal.

2. The circuit of claim 1, further comprising an amplifier receiving the A.C. signal and providing an amplified signal.

3. The circuit of claim 2, further comprising a divider receiving the amplified signal and providing an output signal, the frequency of the output signal being smaller than the frequency of the amplified signal.

4. The circuit of claim 1, further comprising:
a frequency divider receiving said A.C. signal and providing an additional A.C. signal, where the divider can apply to the A.C. signal a division coefficient from among M division coefficients, M being an integer at least equal to 2; and
a delta-sigma converter receiving a set point indicating a desired frequency value and providing an additional control signal that can take M values, the value of the additional control signal being capable of changing on each rising or falling edge of the additional A.C. signal, each division coefficient being associated with one of the M values of the additional control signal, the successive durations of the halfwaves of the additional A.C. signal corresponding to the successive values of the control signal, the A.C. signal exhibiting a frequency equal, on average, to the desired frequency.

5. The circuit of claim 4, further comprising an injection locked oscillator receiving said A.C. signal or the additional A.C. signal and providing an output signal.

6. The circuit of claim 5, wherein the locking frequency range of the oscillator comprises a frequency equal to an integral multiple of said desired frequency.

7. The circuit of claim 1, wherein at least one nanomagnetic oscillator comprises:
a first portion of a magnetic material in which the orientations of the spins of the particles of the first portion are set, a second portion of a magnetic material in which the orientations of the spins of the particles of the second portion are capable of varying, and a third portion of an at least partially conductive material interposed between the first and second portions;
a current source comprising a first terminal connected to the first portion and a second terminal connected to the second portion; and
a source adapted to apply a magnetic field on the first and second portions.

8. A circuit for providing an A.C. signal comprising:
a number N of nanomagnetic oscillators, N being an integer greater than or equal to 2, each nanomagnetic oscillator providing a periodic signal, the N nanomagnetic oscillators being adapted to provide the periodic signals at a same frequency plus or minus the frequency dispersions of the nanomagnetic oscillators;
a unit for providing a control signal that can take N values, each periodic signal being associated with one of the values of the control signal; and
a multiplexer receiving the N periodic signals and the control signal and providing the A.C. signal equal to one of the periodic signals according to the value of the control signal
wherein the unit is a delta-sigma converter receiving a set point indicating a desired frequency value, the value of the control signal being capable of changing on each rising or falling edge of the A.C. signal, and wherein the frequency of each periodic signal is equal to one of N predefined frequency values, the successive durations of the halfwaves of the A.C. signal corresponding to the successive values of the control signal, the A.C. signal exhibiting a frequency on average equal to the desired frequency.

9. The circuit of claim 8, further comprising an amplifier receiving the A.C. signal and providing an amplified signal.

10. The circuit of claim 9, further comprising a divider receiving the amplified signal and providing an output signal, the frequency of the output signal being smaller than the frequency of the amplified signal.

11. The circuit of claim 8, further comprising an injection locked oscillator receiving said A.C. signal or the additional A.C. signal and providing an output signal.

12. The circuit of claim 11, wherein the locking frequency range of the oscillator comprises a frequency equal to an integral multiple of said desired frequency.

13. The circuit of claim 8, wherein at least one nanomagnetic oscillator comprises:
a first portion of a magnetic material in which the orientations of the spins of the particles of the first portion are set, a second portion of a magnetic material in which the orientations of the spins of the particles of the second portion are capable of varying, and a third portion of an at least partially conductive material interposed between the first and second portions;
a current source comprising a first terminal connected to the first portion and a second terminal connected to the second portion; and
a source capable of applying a magnetic field on the first and second portions.
